(19) United States
(12) Patent Application Publication
(10) Pub. No.: US 2025/0304427 A1
(43) Pub. Date: Oct. 2, 2025

(54) MICRO-ELECTROMECHANICAL DEVICES

(71) Applicant: Honeywell International Inc., Charlotte, NC (US)

(72) Inventor: Paul W. Dwyer, Seattle, WA (US)

(21) Appl. No.: 18/623,456

(22) Filed: Apr. 1, 2024

(51) Int. Cl. B81B 3/00; B81C 1/00

(52) U.S. Cl. CPC B81B 3/0021; B81C 1/00142; B81B 2201/0235; B81B 2201/0271; B81B 2203/0109; B81C 2201/0176

(57) ABSTRACT

A micro-electromechanical device may include a first resonator tine and a second resonator tine configured to resonate in-plane and out-of-phase with each other. A graphene layer may be deposited over at least a portion of the first resonator tine.

### TECHNICAL FIELD

The present disclosure relates to micro-electromechanical devices, for example, vibrating beam accelerometers.

### BACKGROUND

Accelerometers function by detecting a displacement of a proof mass under inertial forces. In one example, an accelerometer may detect the displacement of a proof mass by the change in frequency of a resonator connected between the proof mass and a support base. A resonator, which may be designed to change frequency proportional to the load applied to the resonator by the proof mass under acceleration. The resonator may be electrically coupled to an oscillator, or other signal generation circuit, which causes the resonator to vibrate at its resonant frequency.

### SUMMARY

In general, the disclosure describes micro-electromechanical devices including a resonator tine including a graphene layer. The graphene layer may act as a conductive trace, allowing excitation of the resonator tine. The graphene layer may be used instead of a conductive trace including gold and/or chromium, and may exhibit a higher flexibility and conformance with the resonator tine during resonation than the conductive trace including gold and/or chromium.

In some examples, an example micro-electromechanical device includes a first resonator tine and a second resonator tine configured to resonate in-plane and out-of-phase with each other. A graphene layer may be deposited over at least a portion of the first resonator tine.

In some examples, an example method is provided for fabricating a micro-electromechanical device. The device includes a first resonator tine and a second resonator tine configured to resonate in-plane and out-of-phase with each other. The method may include forming a graphene layer over at least a portion of the first resonator tine.

The details of one or more examples are set forth in the accompanying drawings and the description below. Other features, objects, and advantages will be apparent from the description and drawings, and from the claims.

### BRIEF DESCRIPTION OF THE FIGURES

The details of one or more examples are set forth in the accompanying drawings and the description below. Other features, objects, and advantages will be apparent from the description and drawings, and from the claims.

FIG. 1A is a diagram illustrating a top view of an example micro-electromechanical device including a proof mass assembly.

FIG. 1B is a diagram illustrating a cross-sectional side view of the micro-electromechanical device of FIG. 1A along line AA-AA.

FIG. 2A is a diagram illustrating a top view of an example resonator including a first resonator tine and a second resonator tine.

FIG. 2B is a diagram illustrating a partial cross-sectional view of the resonator of FIG. 2A along line BB-BB.

FIG. 3A is a partial cross-sectional view of a micro-electromechanical assembly in a first configuration in a manufacturing process.

FIG. 3B is a partial cross-sectional view of the micro-electromechanical assembly of FIG. 3A in a second configuration in the manufacturing process.

FIG. 4 is a flow diagram illustrating an example technique for forming a micro-electromechanical device.

FIG. 5 is a block diagram illustrating an accelerometer system.

### DETAILED DESCRIPTION

Navigation systems and positioning systems rely on the accuracy of micro-electromechanical devices (e.g., accelerometers, gyroscopes) to perform operations in various environments. Due to the different types of materials used in producing such accelerometers, strains may be imposed on the various components due to changing temperatures or other environmental conditions. These changes may cause errors and reduce the overall accuracy, precision, or sensitivity of the device. For example, one source of errors in a vibrating beam accelerometer (VBA) relates to plastic deformations in metallized conductive regions on resonator tines of double-ended tuning forks (DETFs), which contribute to a noise floor of the accelerometer.

In particular, the noise floor of DETFs may constrain the precision of open-loop digital accelerometers. For example, a DETF or another oscillator may include a piezoelectric substrate (e.g., quartz) and a conductive pattern (e.g., a trace including a chromium layer and a gold layer). A DETF uses the conductive pattern to excite the vibration frequency of the DETF in VBAs.

Gold may be susceptible to mechanical deformations, and allow plastic deformation, which in turn may be a factor in the resultant noise floor of the accelerometer. Such a contribution to the noise floor may constrain the precision of the accelerometer. Deformations arising at a chromium-gold interface or at a pattern-substrate interface (e.g., between quartz and chromium) may degrade the ability to precisely determine a frequency change when an acceleration is applied, and thus, impact navigation using the accelerometer including the DETF.

In some examples, as described herein, a conductive pattern on a resonating component (e.g., a resonator tine) of a micro-electromechanical device includes graphene (for example, instead of a conductive pattern including a metal trace). Graphene is sufficiently conductive to excite the vibration frequency of the DETF, but also sufficiently elastic to accommodate strains without substantial disruptions at the pattern-substrate interface. Thus, a micro-electromechanical device including a graphene layer (e.g., instead of a chromium/gold conductive pattern) on a resonator tine may exhibit a reduced noise floor of the device. For example, an using a graphene layer as a conductive pattern on a resonator tine in an accelerometer may promote navigation capabilities of the accelerometer. In some examples, the graphene layer is a single-atomic layer (including only carbon). To avoid surface charging of exposed substrate, the graphene layer may be formed with little to no exposed substrate, or minimally exposed substrate compatible with circuitry required to energize the tines into oscillation.

The graphene layer may be deposited on a resonator tine by chemical vapor deposition from a carbon source (e.g., methane) on a substrate of the resonator tine. For example, the substrate may include crystalline quartz, and carbon atoms may be deposited from the carbon source on the substrate to ultimately form graphene. An intermediate layer may be used to promote the deposition of carbon in a predetermined pattern on the substrate. For example, an intermediate layer including a metal (e.g., copper, nickel, or molybdenum) may be deposited in the predetermined pattern onto the substrate. Carbon atoms from the carbon source (e.g., generated by thermal decomposition) will accrue on the surface of the intermediate layer (for example, by a selective or preferential deposition of carbon on metal), and the carbon may be deposited substantially only on the intermediate layer. Thus, the carbon may be deposited as graphene in substantially the same pattern as that of the intermediate layer.

The pattern may be formed using any suitable technique, including etching, for example, by laser ablation. A layer of gold may be applied to the intermediate pattern to resist oxidation, and reduce or prevent oxidative changes to material properties of the intermediate layer. The thickness of the protective layer of gold may be less than the thickness of a conductive pattern substantially formed of gold itself, and thus, reduce the noise floor effect by reducing the thickness of gold that may be used.

In some examples, the carbon source is thermally decomposed at a relatively high temperature to generate carbon atoms deposited as graphene. For example, methane may be decomposed at about 1000° C. However, certain substrates (e.g., quartz) may tend to destabilize or transform at such high temperatures. In examples, the substrate (e.g., crystalline quartz) may be retained in a cool zone of a chemical vapor deposition chamber, such that the substrate remains cooler than the vapor temperature. For example, the cool zone may maintain the quartz at a maximum temperature below 750° C. to protect the quartz, while allowing decomposing of methane to carbon in vapor at higher temperatures such as 1000° C.

In some examples, the intermediate layer used to deposit carbon in the pattern is etched from underneath the graphene layer after the graphene layer is formed, so that the graphene layer can attach directly to the substrate (e.g., by van der Waals forces). In other examples, the intermediate layer is left intact.

After the graphene layer is deposited, a portion of the graphene layer may be overlaid with a conductive pad for subsequent wire bonding. For example, the conductive pad may include a layer including chromium and gold.

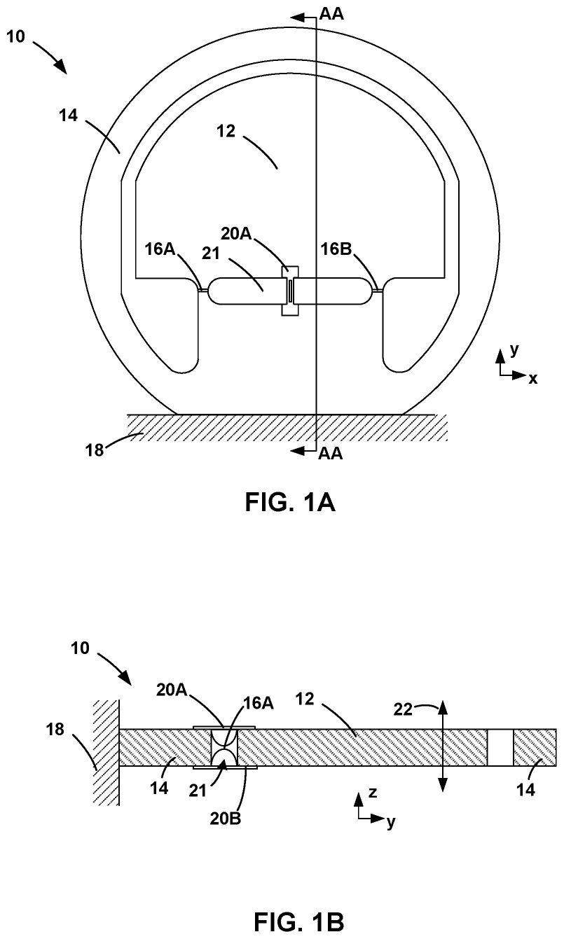

FIGS. 1A and 1B are diagrams illustrating a top view (FIG. 1A) and a cross-sectional side view (FIG. 1B, taken along line AA-AA of FIG. 1A) of an example micro-electromechanical device including a proof mass assembly 10. Proof mass assembly 10 includes a proof mass 12 connected to a proof support 14 by flexures 16A and 16B. Proof mass assembly 10 also includes at least two resonators 20A and 20B bridging a gap 21 between proof mass 12 and proof support 14. Resonators 20A and 20B each have opposing ends mounted to proof mass 12 and proof support 14, respectively. Proof mass assembly 10 may be a proof mass assembly of a vibrating beam accelerometer (VBA).

VBAs operate by monitoring a differential change in frequencies between resonators 20A and 20B. Each of resonators 20A and 20B, also referred to as double ended tuning forks (DETFs), will vibrate at a certain frequency depending on the axial strain (e.g., compression or tension exerted in the y-axis direction of FIGS. 1A and 1B) exerted on the respective resonator 20A or 20B. During operation, proof support 14 may be directly or indirectly mounted to an object 18 (e.g., aircraft, missile, orientation module, etc.) that undergoes acceleration or angle change and causes proof mass 12 to experience inertial displacements in a direction perpendicular to the plane defined by flexures 16A and 16B (e.g., in the direction of arrows 22 or in the direction of the z-axis of FIG. 1B). The deflection of proof mass 12 induces axial tension on one of resonators 20A and 20B and axial compression on the other depending on the direction of the force. The different relative strains on resonators 20A and 20B alter the respective vibration frequencies of the resonators 20A and 20B. By measuring these changes, the direction and magnitude of the force exerted on object 18, and thus the acceleration, can be measured.

Proof mass assembly 10 may include additional components that are used to induce an oscillating frequency across resonators 20A and 20B such as one or more electrical traces, piezoelectric drivers, electrodes, and the like, or other components that may be used with the final construction of the accelerometer such as stators, permanent magnets, capacitance pick-off plates, dampening plates, force-rebalance coils, and the like, which are not shown in FIGS. 1A and 1B. One or more of such components may be incorporated in proof mass assembly 10 or the accelerometer by those having ordinary skill in the art.

As shown in FIG. 1A, proof support 14 may be a planar ring structure that substantially surrounds proof mass 12 and substantially maintains flexures 16A and 16B and proof mass 12 in a common plane (e.g., the x-y plane of FIGS. 1A and 1B). Although proof support 14 as shown in FIG. 1A is a circular shape, it is contemplated that proof support 14 may be any shape (e.g., square, rectangular, oval, or the like) and may or may not surround proof mass 12.

Proof mass 12, proof support 14, and flexures 16 may be formed using any suitable material. In some examples, proof mass 12, proof support 14, and flexures 16 may be made of a silicon-based material, a metal alloy such as nickel-chromium alloy or Inconel, or the like.

In some examples, resonators 20A and 20B include a piezoelectric material, for example, at least one of quartz (SiO₂), Berlinite (AlPO₄), gallium orthophosphate (GaPO₄), thermaline, barium titanate (BaTiO₃), lead zirconate titanate (PZT), zinc oxide (ZnO), or aluminum nitride (AlN), or the like. In some examples, resonators 20A and 20B include silicon or a silicon-based material. In some examples, resonators 20A and 20B include quartz as a substrate, and may include one or more coatings or layers over the substrate.

Although proof mass assembly 10 is described as having two resonators 20A and 20B, in other examples (not illustrated), a proof mass assembly or an accelerometer system may include less than two resonators or greater than two resonators. For example, a proof mass assembly or an accelerometer system may include one resonator, or four or more resonators.

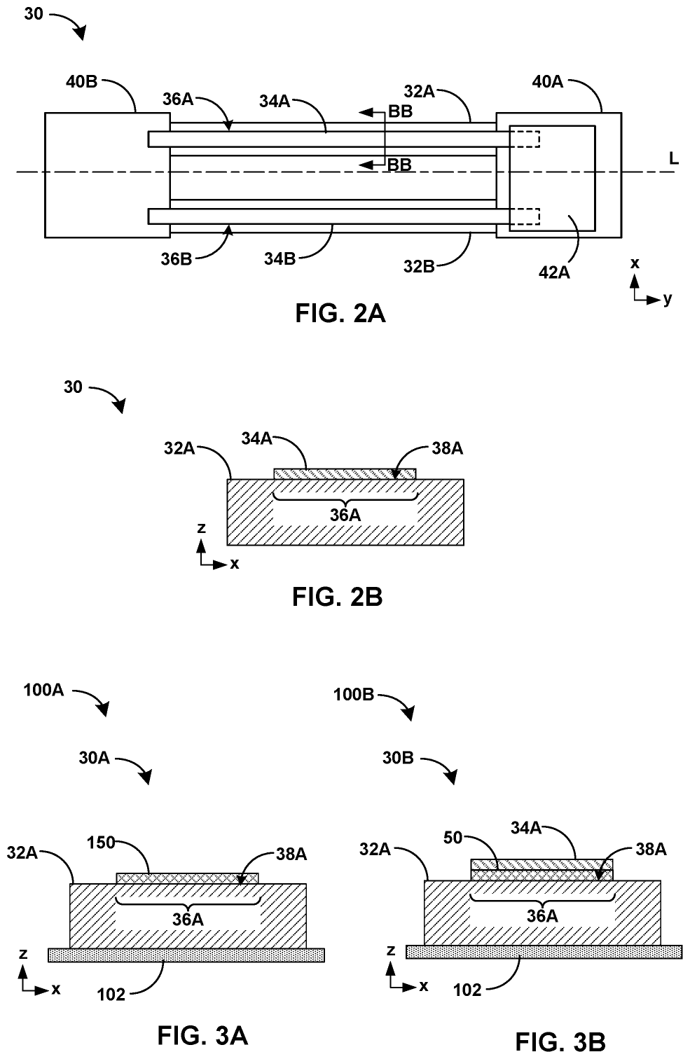

FIG. 2A is a diagram illustrating a top view of an example resonator 30 (e.g., one of resonators 20A and 20B) that includes a first resonator tine 32A and a second resonator tine 32B. FIG. 2B is a diagram illustrating a partial cross-sectional view of resonator 30 of FIG. 2A along line BB-BB. Resonator 30 may be referred to as a DETF.

First resonator tine 32A and second resonator tine 32B are configured to resonate in-plane and out-of-phase with each other. First resonator tine 32A and second resonator tine 32B may extend parallel to each other along a longitudinal axis L. First resonator tine 32A and second resonator tine 32B may each include any material described with reference to resonators 20A. For example, first resonator tine 32A and second resonator tine 32A may each include a piezoelectric material. In some examples, the piezoelectric material includes quartz. In some such examples, a bulk or a substrate of each of first resonator tine 32A and second resonator tine 32A consists of, or consists essentially of, quartz.

A graphene layer 34A is deposited over at least a portion 36A of first resonator tine 32A. For example, graphene layer 34A may be a conductive trace along first resonator tine 32A, and may be configured to excite a vibration frequency of first resonator tine 32A. In some examples, graphene layer 34A is a first graphene layer, and resonator 30 further includes a second graphene layer 34B along at least a portion 36B of second resonator tine 32B.

Graphene layers 34A and 34B may directly contact first resonator tine 32A and second resonator tine 32B respectively. For example, graphene layer 34A may contact a surface 38A defined by portion 36A of first resonator tine 32A. In such examples, a graphene-substrate interface (e.g., a graphene-quartz interface) may be present between first resonator tine 32A and graphene layer 34A.

In some examples, resonator 30 further includes an intermediate layer between graphene layer 34A and portion 38A of first resonator tine 32A (shown in FIG. 3B). For example, the intermediate layer may be coextensive with graphene layer 34A or portion 38A along which graphene layer 34A is deposited. The intermediate layer may facilitate one or both of deposition or retention of graphene layer 34A on first resonator tine 32A. The intermediate layer may include a metal or an alloy. For example, the metal or the alloy may selectively or preferentially receive carbon atoms deposited from a carbon source. In some examples, the intermediate layer includes one or more of copper, nickel, or molybdenum.

The intermediate layer may be formed or deposited in a predetermined conductive pattern using any suitable technique including, but not limited, to masking, photo chemical etching, laser etching, mechanical machining, or the like. Graphene layer 34A may thus be formed substantially in the predetermined pattern by depositing carbon atoms on the intermediate layer. In some examples, a same or similar intermediate layer is present between graphene layer 34B and a portion of second resonator tine 32B.

Resonator 30 may further include structures configured to hold first resonator tine 32A and second resonator tine 32B during resonation of resonator device 30. For example, resonator 30 may further include a first bond pad 40A and a second bond pad 40B at opposed ends of resonator 30 along longitudinal axis L. First resonator tine 32A and second resonator tine 32B may extend between first bond pad 40A and second bond pad 40B, along longitudinal axis L. First bond pad 40A and second bond pad 40B of resonator 30 may be secured to either a proof mass or proof support, respectively, for example, in a similar manner as described with reference to FIGS. 1A and 1B. In some examples, resonator 30 includes an integral or unitary body defining each of first resonator tine 32A, second resonator tine 32B, first bond pad 40A, and second bond pad 40B. For example first resonator tine 32A, second resonator tine 32B, first bond pad 40A, and second bond pad 40B may be defined by portions of a unitary quartz body.

First graphene layer 34A may extend along first resonator tine 32A between first bond pad 40A and second bond pad 40B. Similarly, second graphene layer 34A may extend along second resonator tine 32B between first bond pad 40A and second bond pad 40B. For example, a length of first graphene layer 34A may be greater than a length of first resonator tine 32A (in a direction along longitudinal axis L). For example, a middle portion of first graphene layer 34A may be configured to extend along an entire length of first resonator tine 32A, and resonate with first resonator tine 32A, while opposing end portions of first graphene layer 34A may be configured to extend beyond respective ends of first resonator tine 32A respectively to first bond pad 40A and second bond pad 40B. The opposing end portions of first graphene layer 34A may remain static over first bond pad 40A and second bond pad 40B while first resonator tine 32A resonates. Similarly, opposing end portions of second graphene layer 34B may remain static over first bond pad 40A and second bond pad 40B while second resonator tine 32B resonates. In some examples, one or both static end portions of first graphene layer 34A or second graphene layer 34B are at least 5%, at least 10%, at least 15%, or at least 20%, of respective lengths of first graphene layer 34A or second graphene layer 34B.

First graphene layer 34A may not be coextensive with a major surface of first resonator tine 32A. For example, a width of first graphene layer 34A may be less than a width of first resonator tine 32A (in a direction transverse to longitudinal axis L). Similarly, a width of second graphene layer 34B may be less than a width of second resonator tine 32B (in a direction transverse to longitudinal axis L). For example, one or both of first graphene layer 34A or second graphene layer 34B may have respective widths that are at least 5%, at least 10%, at least 15%, at least 20%, or at least 25%, less than widths of first resonator tine 32A and second resonator tine 32B, respectively. In other examples, first graphene layer 34A and second graphene layer 34B may have widths that are respectively the same as the widths of first resonator tine 32A and second resonator tine 32B. In some examples, first graphene layer 34A and second graphene layer 34B have a same width.

First graphene layer 34A and second graphene layer 34B may have any suitable thickness in a direction transverse to longitudinal axis. In some examples, one or both of first graphene layer 34A and second graphene layer 34B include graphene monolayers having substantially a single atomic thickness of carbon. In other examples, one or both of first graphene layer 34A and second graphene layer 34B have a thickness greater than graphene monolayers. For example, the thickness may be in a range of from one monolayer to ten monolayers, or from one monolayer to five monolayers.

A graphene layer (e.g., first graphene layer 34A or second graphene layer 34B) may define an electrical trace extending between first bond pad 40A and second bond pad 40B. For example, first graphene layer 34A or second graphene layer 34B may receive an electrical signal from excitation circuitry, and in response, excite a vibration frequency of first resonator tine 32A and second resonator tine 32B.

Resonator 30 may further include conductive structures configured to electrically couple graphene layers 34A and 34B with excitation circuitry. For example, first bond pad 40A may include a conductive coating 42A partially overlaying first graphene layer 34A and second graphene layer 34B. Conductive coating 42A may include any suitable conductive material, for example, a metal or an alloy. In some examples, conductive coating 42A includes gold.

Thus, resonator 30 may include a double-ended tuning fork including first resonator tine 32A and second resonator tine 32B, for example, configured to resonate in response to an excitation signal received by first graphene layer 34A and second graphene layer 34B from excitation circuitry.

While resonator 30 may be used in a proof mass assembly as described with reference to FIGS. 1A and 1B, in other examples, any other micro-electromechanical device may include resonator 30, or one or both of first resonator tine 32A or second resonator tine 32B.

Micro-electromechanical devices or assemblies, proof mass assemblies, or resonators according to the present disclosure may be formed using any suitable technique. FIGS. 3A and 3B illustrate different configurations of a micro-electromechanical in a manufacturing process.

FIG. 3A is a partial cross-sectional view of a micro-electromechanical assembly in a first configuration 100A in a manufacturing process. Micro-electromechanical assembly 100A includes a resonator precursor 30A supported by a platform 102. Resonator precursor 30A includes resonator tine 32A described with reference to FIGS. 2A and 2B. An intermediate layer 150 is deposited on surface 38A defined by portion 36A of resonator tine 32A. Intermediate layer 150 may be configured to selectively or preferentially accrue carbon atoms from a carbon source to form a graphene layer on intermediate layer 150. Intermediate layer 150 may include a metal or an alloy. For example, intermediate layer 150 may include one or more of copper, nickel, or molybdenum. Intermediate layer 150 may be deposited in a predetermined conductive pattern on surface 38A, for example, by masking to define the conductive pattern, followed by deposition of a material using, for example, chemical vapor deposition, physical vapor deposition (e.g., electron beam evaporation or sputtering), or the like.

In some examples, an antioxidative layer (not shown) is deposited over intermediate layer 150. The antioxidative layer may include any suitable antioxidative material, for example, gold. The antioxidative layer may resist or prevent degradation of mechanical properties of intermediate layer 150 by exposure to oxygen in course of further processing or use in an environment including oxygen.

FIG. 3B is a partial cross-sectional view of the micro-electromechanical assembly of FIG. 3A in a second configuration 100B in the manufacturing process. Micro-electromechanical assembly 100B includes a resonator precursor 30B. Resonator precursor 30B includes graphene layer 34A deposited on resonator precursor 30A, in particular, on intermediate layer 150. For example, resonator precursor 30A may be exposed to a carbon source (e.g., methane), and the carbon source may be decomposed to generate carbon atoms that are selectively deposited on intermediate layer 150 to form graphene layer 34A. For example, substantially no carbon atoms are deposited over first resonator tine 32A other than on intermediate layer 150.

Resonator precursor 30B may be further processed, for example, to remove intermediate layer 150 by etching, to form resonator 30A as illustrated in FIGS. 2A and 2B. In other examples, intermediate layer 150 is not removed, and resonator precursor 30B may be itself used as a resonator.

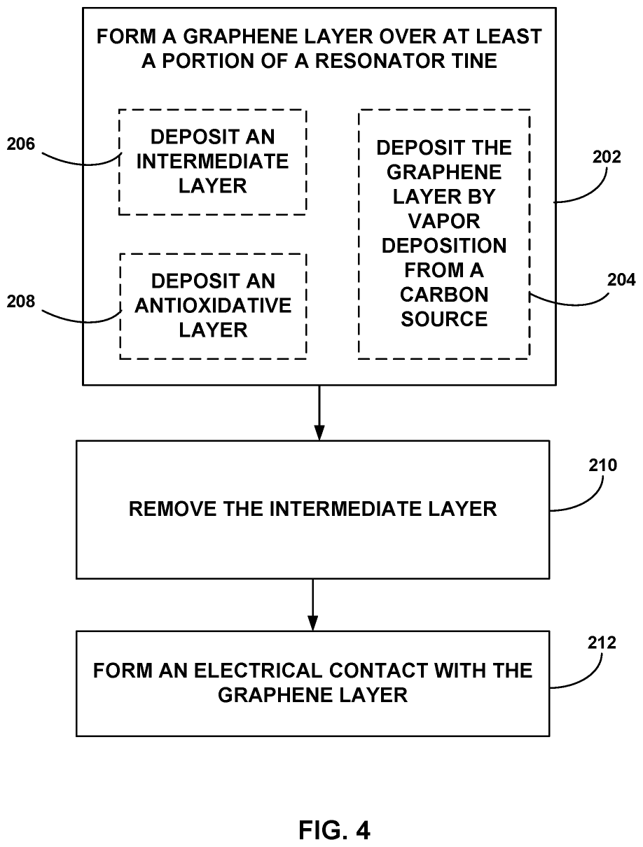

FIG. 4 is a flow diagram illustrating an example technique for forming a micro-electromechanical device according to the present disclosure, for example, proof mass assembly 10 or resonator 30. While the technique shown in FIG. 4 is described with respect to proof mass assembly 10 and resonator 30, in other examples, the techniques may be used to form other micro-electromechanical devices or assemblies, accelerometers, resonators or portions of accelerometers that include different configurations, and micro-electromechanical devices or assemblies, accelerometers, or resonators described herein may be form using other techniques.

In some examples, an example method is provided for fabricating proof mass assembly 10. Proof mass assembly includes first resonator tine 32A and second resonator tine 32B configured to resonate in-plane and out-of-phase with each other. The method may include forming graphene layer 34A over at least portion 36A of first resonator tine 32A (202). As described with reference to FIGS. 2A and 2B, first resonator tine 32A and second resonator tine 32B may extend between first bond pad 40A and second bond pad 40B. Graphene layer 34A may extend along first resonator tine 32A between first bond pad 40A and second bond pad 40B. The method may further include forming graphene layer 34B over at least a portion of second resonator tine 32B.

Forming the graphene layer (202) may include vapor deposition of the graphene layer from a carbon source, for example, chemical vapor deposition (204). The carbon source may include an organic gas, for example, methane, or any gas that may be decomposed or reduced to deposit carbon atoms to form graphene. The vapor deposition (204) may include heating the carbon source to a decomposition temperature to cause decomposition of the carbon source to generate carbon atoms. In some examples, the decomposition temperature is at least 800° C., at least 900° C., or at least 1000° C. The carbon atoms are deposited over at least portion 36A to form graphene layer 34A.

As described with reference to FIGS. 2A and 2B, first resonator tine 32A may include a piezoelectric material, for example, quartz. Because the piezoelectric material may be susceptible to thermal degradation at the decomposition temperature, first resonator tine 32A may be maintained in a cool zone during the deposition. For example, first resonator tine 32A may be maintained at a temperature less than 900° C., or less than 800° C., less than 750° C., or less than 600° C., during chemical vapor deposition of graphene layer 34 by decomposition of the carbon source. In some examples, first resonator tine 32A includes crystalline quartz is maintained at a temperature less than 573° C. to resist an alpha/beta quartz transformation.

In some examples, forming the graphene layer (202) includes depositing intermediate layer 150 including a metal or an alloy over at least portion 36A of first resonator tine 32A (206). In some such examples, forming graphene layer 34A further includes depositing carbon atoms (204) on intermediate layer 150 to form graphene layer 34A on intermediate layer 150. For example, carbon atoms may preferentially or selectively accrue substantially only on intermediate layer 150, and not on other regions or portions of first resonator tine 32A. Intermediate layer 150 may include one or more of copper, nickel, or molybdenum.

The method may include forming additional layers. For example, the method may further include forming an antioxidative layer between intermediate layer 150 and the graphene layer (208). The antioxidative layer may include gold, or any other suitable antioxidant composition. In some examples, the antioxidative layer consists of or consists essentially of a gold layer. Forming graphene layer 202 may thus include first depositing intermediate layer 150 (206), followed by depositing the antioxidative layer (208), followed by depositing graphene layer 34A by vapor deposition (204). Thus, graphene layer 34A may be deposited on the antioxidative layer. In other examples, the method does not include one or both of depositing intermediate layer 150 (206) or depositing the antioxidative layer (208), and may result in deposition of graphene layer 34A directly on surface 38A defined by portion 36A of first resonant tine 32A.

Intermediate layer 150 may be retained, or may be removed, after depositing graphene layer 34A (204). For example, the method may further include, after depositing the carbon atoms to form graphene layer over intermediate layer 150, etching away intermediate layer 150 to allow graphene layer 34A to contact portion 36A of first resonator tine 32 (210).

The method may further include forming an electrical contact with the graphene layer (212). For example, the method may further include depositing conductive coating 42A partially overlaying graphene layer 34A on first bond pad 40. In some examples, conductive coating 42A includes, consists of, or consists essentially of a gold coating. Forming the electrical contact (212) may include chemical vapor deposition, physical vapor deposition (e.g., electron beam evaporation or sputtering), or the like, to form conductive coating 42A.

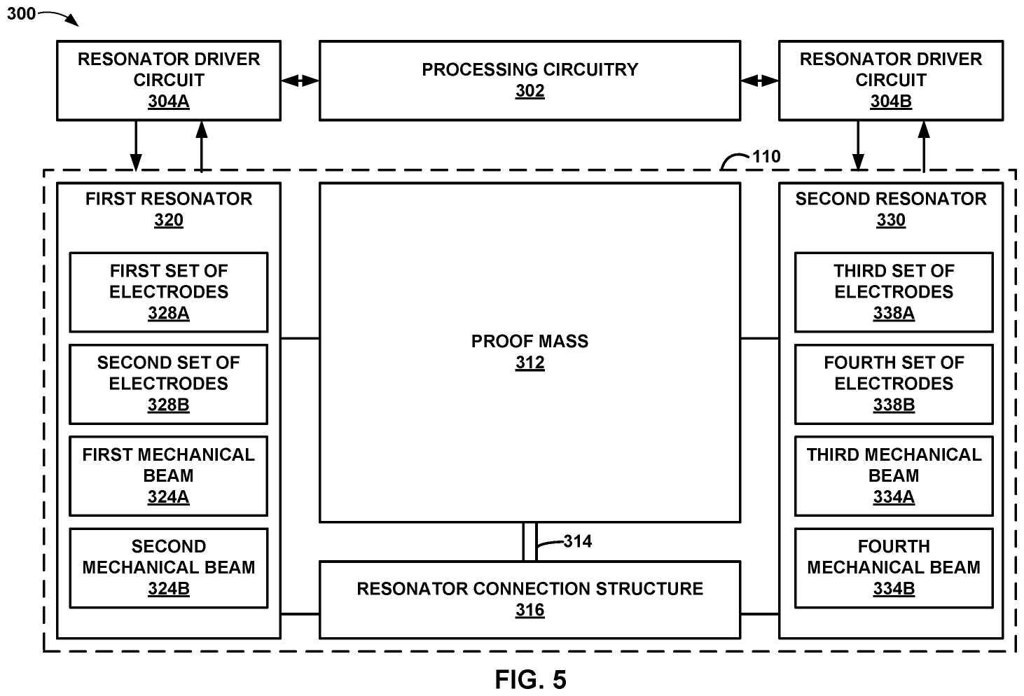

FIG. 5 is a block diagram illustrating an accelerometer system 300, in accordance with one or more techniques of this disclosure. As illustrated in FIG. 5, accelerometer system 300 includes processing circuitry 302, resonator driver circuits 304A-304B (collectively, “resonator driver circuits 304”), and proof mass assembly 310. Proof mass assembly 310 may be substantially similar to proof mass assembly 10 described above. Proof mass assembly 310 includes proof mass 312, resonator connection structure 316, first resonator 320, and second resonator 330. Proof mass 312 may be substantially similar to proof mass 12, resonator connection structure 116 may be substantially similar to proof support 14, and resonators 320, 330 may be substantially similar to resonators 20A, 20B and/or resonator 30, described above.

First resonator 320 includes first mechanical beam 324A and second mechanical beam 324B (collectively, “mechanical beams 324”), and first set of electrodes 328A and second set of electrodes 328B (collectively, “electrodes 328”). Second resonator 330 includes third mechanical beam 334A and fourth mechanical beam 334B (collectively, “mechanical beams 334”), and third set of electrodes 338A and fourth set of electrodes 338B (collectively, “electrodes 338”).

Accelerometer system 300 may, in some examples, be configured to determine an acceleration associated with an object (not illustrated in FIG. 5) based on a measured vibration frequency of one or both of first resonator 320 and second resonator 330 which are connected to proof mass 312. In some examples, the vibration of first resonator 320 and second resonator 330 is induced by drive signals emitted by resonator driver circuit 304A and resonator driver circuit 304B, respectively. In turn, first resonator 320 may output a first set of sense signals and second resonator 330 may output a second set of sense signals and processing circuitry 302 may determine an acceleration of the object based on the first set of sense signals and the second set of sense signals.

Processing circuitry 302, in some examples, may include one or more processors that are configured to implement functionality and/or process instructions for execution within accelerometer system 300. For example, processing circuitry 302 may be capable of processing instructions stored in a storage device. Processing circuitry 302 may include, for example, microprocessors, digital signal processors (DSPs), application specific integrated circuits (ASICs), field-programmable gate arrays (FPGAs), or equivalent discrete or integrated logic circuitry, or a combination of any of the foregoing devices or circuitry. Accordingly, processing circuitry 302 may include any suitable structure, whether in hardware, software, firmware, or any combination thereof, to perform the functions ascribed herein to processing circuitry 302.

A memory (not illustrated in FIG. 5) may be configured to store information within accelerometer system 300 during operation. The memory may include a computer-readable storage medium or computer-readable storage device. In some examples, the memory includes one or more of a short-term memory or a long-term memory. The memory may include, for example, random access memories (RAM), dynamic random access memories (DRAM), static random access memories (SRAM), magnetic discs, optical discs, flash memories, or forms of electrically programmable memories (EPROM) or electrically erasable and programmable memories (EEPROM). In some examples, the memory is used to store program instructions for execution by processing circuitry 302.

In some examples, resonator driver circuit 304A may be electrically coupled to first resonator 320. Resonator driver circuit 304A may output a first set of drive signals to first resonator 320, causing first resonator 320 to vibrate at a resonant frequency. Additionally, in some examples, resonator driver circuit 304A may receive a first set of sense signals from first resonator 320, where the first set of sense signals may be indicative of a mechanical vibration frequency of first resonator 320. Resonator driver circuit 304A may output the first set of sense signals to processing circuitry 302 for analysis. In some examples, the first set of sense signals may represent a stream of data such that processing circuitry 302 may determine the mechanical vibration frequency of first resonator 320 in real-time or near real-time.

In some examples, resonator driver circuit 304B may be electrically coupled to second resonator 330. Resonator driver circuit 304B may output a second set of drive signals to second resonator 330, causing second resonator 330 to vibrate at a resonant frequency. Additionally, in some examples, resonator driver circuit 304B may receive a second set of sense signals from second resonator 330, where the second set of sense signals may be indicative of a mechanical vibration frequency of first resonator 330. Resonator driver circuit 304B may output the second set of sense signals to processing circuitry 302 for analysis. In some examples, the second set of sense signals may represent a stream of data such that processing circuitry 302 may determine the mechanical vibration frequency of second resonator 330 in real-time or near real-time.

Proof mass assembly 310 may secure proof mass 312 to resonator connection structure 316 using first resonator 320 and second resonator 330. For example, proof mass 312 may be secured to resonator connection structure 316 in a first direction with hinge flexure 314. Hinge flexure 314 may be substantially similar to flexures 16A, 16A described above. Proof mass 312 may be secured to resonator connection structure 316 in a second direction with first resonator 320 and second resonator 330. Proof mass 312 may be configured to pivot about hinge flexure 314, applying force to first resonator 320 and second resonator 330 in the second direction. For example, if proof mass 312 pivots towards first resonator 320, proof mass 312 applies a compression force to first resonator 320 and applies a tension force to second resonator 330. If proof mass 312 pivots towards second resonator 330, proof mass 312 applies a tension force to first resonator 320 and applies a compression force to second resonator 330.

An acceleration of proof mass assembly 310 may affect a degree to which proof mass 312 pivots about hinge flexure 314. As such, the acceleration of proof mass assembly 310 may determine an amount of force applied to first resonator 320 and an amount of force applied to second resonator 330. An amount of force (e.g., compression force or tension force) applied to resonators 320, 330 may be correlated with an acceleration vector of proof amass assembly 310, where the acceleration vector is normal to hinge flexure 314.

In some examples, the amount of force applied to first resonator 320 may be correlated with a resonant frequency in which first resonator 320 vibrates in response to resonator driver circuit 304A outputting the first set of drive signals to first resonator 320. For example, first resonator 320 may include mechanical beams 324. In this way, first resonator 320 may represent a DETF structure, where each mechanical beam of mechanical beams 324 vibrates at the resonant frequency in response to receiving the first set of drive signals. Electrodes 328 may generate and/or receive electrical signals indicative of a mechanical vibration frequency of first mechanical beam 324A and a mechanical vibration frequency of second mechanical beam 324B. For example, the first set of electrodes 328A may generate and/or receive a first electrical signal and the second set of electrodes 328B may generate and/or receive a second electrical signal. In some examples, the first electrical signal may be in response to sensing a mechanical vibration frequency of the mechanical beams 324 (e.g., both mechanical beams 324A and 324B) via the first set of electrodes 328A, e.g., a resonant frequency of mechanical beams 324. Resonant driver circuit 304A may receive the first electrical signal and may amplify the first electrical signal to generate the second electrical signal. The second electrical signal may be applied to mechanical beams 324 (e.g., both mechanical beams 324A and 324B) via second set of electrodes 328B, e.g., to drive mechanical beams 324 to vibrate at the resonant frequency. Electrodes 328 may output the first electrical signal and the second electrical signal to processing circuitry 302. Electrodes 328 may be examples of graphene layers 34A and 34B of resonators 20A, 30, described above.

In some examples, the mechanical vibration frequency of first mechanical beam 324A and second mechanical beam 324B are substantially the same when resonator driver circuit 304A outputs the first set of drive signals to first resonator 320. For example, the mechanical vibration frequency of first mechanical beam 324A and the mechanical vibration frequency of second mechanical beam 324B may both represent the resonant frequency of first resonator 320, where the resonant frequency is correlated with an amount of force applied to first resonator 320 by proof mass 312. The amount of force that proof mass 312 applies to first resonator 320 may be correlated with an acceleration of proof mass assembly 310 relative to a long axis of resonator connection structure 316. As such, processing circuitry 302 may calculate the acceleration of proof mass 312 relative to the long axis of resonator connection structure 316 based on the detected mechanical vibration frequency of mechanical beams 324.

In some examples, the amount of force applied to second resonator 330 is correlated with a resonant frequency in which second resonator 330 vibrates in response to resonator driver circuit 304B outputting the second set of drive signals to second resonator 330. For example, second resonator 330 may include mechanical beams 334. In this way, second resonator 330 may represent a DETF structure, where each mechanical beam of mechanical beams 334 vibrates at the resonant frequency in response to receiving the second set of drive signals. Electrodes 338 may generate and/or receive electrical signals indicative of a mechanical vibration frequency of third mechanical beam 334A and a mechanical vibration frequency of fourth mechanical beam 334B. For example, the third set of electrodes 338A may generate and/or receive a third electrical signal and the fourth set of electrodes 338B may generate a fourth electrical signal. In some examples, the third electrical signal may be in response to sensing a mechanical vibration frequency of the mechanical beams 334 (e.g., both mechanical beams 334A and 334B) via the third set of electrodes 338A, e.g., a resonant frequency of mechanical beams 334. Resonant driver circuit 304B may receive the third electrical signal and may amplify the third electrical signal to generate the fourth electrical signal. The fourth electrical signal may be applied to mechanical beams 334 (e.g., both mechanical beams 334A and 334B) via fourth set of electrodes 338B, e.g., to drive mechanical beams 334 to vibrate at the resonant frequency. Electrodes 338 may output the third electrical signal and the fourth electrical signal to processing circuitry 302. Electrodes 338 may be examples of graphene layers 34A and 34B of resonators 20B, 30, described above.

In some examples, the mechanical vibration frequency of the third mechanical beam 334A and the fourth mechanical beam 334B are substantially the same when resonator driver circuit 304B outputs the second set of drive signals to second resonator 330. For example, the mechanical vibration frequency of third mechanical beam 334A and the mechanical vibration frequency of fourth mechanical beam 334B may both represent the resonant frequency of second resonator 330, where the resonant frequency is correlated with an amount of force applied to second resonator 330 by proof mass 312. The amount of force that proof mass 312 applies to second resonator 330 may be correlated with an acceleration of proof mass assembly 310 relative to a long axis of resonator connection structure 316. As such, processing circuitry 302 may calculate the acceleration of proof mass 312 relative to the long axis of resonator connection structure 316 based on the detected mechanical vibration frequency of mechanical beams 334.

In some cases, processing circuitry 302 calculates an acceleration of proof mass assembly 310 relative to the long axis of resonator connection structure 316 based on a difference between the detected mechanical vibration frequency of mechanical beams 324 and the detected mechanical vibration frequency of mechanical beams 334. When proof mass assembly 310 accelerates in a first direction along the long axis of resonator connection structure 316, proof mass 312 pivots towards first resonator 320, causing proof mass 312 to apply a compression force to first resonator 320 and apply a tension force to second resonator 330. When proof mass assembly 310 accelerates in a second direction along the long axis of resonator connection structure 316, proof mass 312 pivots towards second resonator 330, causing proof mass 312 to apply a tension force to first resonator 320 and apply a compression force to second resonator 330. A resonant frequency of a resonator which is applied a first compression force may be greater than a resonant frequency of the resonator which is applied a second compression force, when the first compression force is less than the second compression force. A resonant frequency of a resonator which is applied a first tension force may be greater than a resonant frequency of the resonator which is applied a second tension force, when the first tension force is greater than the second tension force.

Although accelerometer system 300 is illustrated as including resonator connection structure 316, in some examples not illustrated in FIG. 5, proof mass 312, first resonator 320, and second resonator 330 are not connected to a resonator connection structure. In some such examples, proof mass 312, first resonator 320, and second resonator 330 are connected to a substrate. For example, hinge flexure 314 may fix proof mass 312 to the substrate such that proof mass 312 may pivot about hinge flexure 314, exerting tension forces and/or compression forces on first resonator 320 and second resonator 330.

Although accelerometer system 300 is described as having two resonators, in other examples not illustrated in FIG. 5, an accelerometer system may include less than two resonators or greater than two resonators. For example, an accelerometer system may include one resonator. Another accelerometer system may include four resonators.

In one or more examples, the accelerometers described herein may utilize hardware, software, firmware, or any combination thereof for achieving the functions described. Those functions implemented in software may be stored on or transmitted over, as one or more instructions or code, a computer-readable medium and executed by a hardware-based processing unit. Computer-readable media may include computer-readable storage media, which corresponds to a tangible medium such as data storage media, or communication media including any medium that facilitates transfer of a computer program from one place to another, e.g., according to a communication protocol. In this manner, computer-readable media generally may correspond to (1) tangible computer-readable storage media which is non-transitory or (2) a communication medium such as a signal or carrier wave. Data storage media may be any available media that can be accessed by one or more computers or one or more processors to retrieve instructions, code and/or data structures for implementation of the techniques described in this disclosure.

Instructions may be executed by one or more processors within the accelerometer or communicatively coupled to the accelerometer. The one or more processors may, for example, include one or more DSPs, general purpose microprocessors, application specific integrated circuits ASICs, FPGAs, or other equivalent integrated or discrete logic circuitry. Accordingly, the term “processor,” as used herein may refer to any of the foregoing structure or any other structure suitable for implementation of the techniques described herein. In addition, in some aspects, the functionality described herein may be provided within dedicated hardware and/or software modules configured for performing the techniques described herein. Also, the techniques could be fully implemented in one or more circuits or logic elements.

The techniques of this disclosure may be implemented in a wide variety of devices or apparatuses that include integrated circuits (ICs) or sets of ICs (e.g., chip sets). Various components, modules, or units are described in this disclosure to emphasize functional aspects of devices configured to perform the disclosed techniques, but do not necessarily require realization by different hardware units. Rather, various units may be combined or provided by a collection of interoperative hardware units, including one or more processors as described above, in conjunction with suitable software and/or firmware.

The following clauses illustrate example subject matter described herein.

Clause 1: A micro-electromechanical device including: a first resonator tine; a second resonator tine configured to resonate in-plane and out-of-phase with each other; and a graphene layer deposited over at least a portion of the first resonator tine.

Clause 2: The device of clause 1, where the graphene layer contacts a surface defined by the portion of the first resonator tine.

Clause 3: The device of clause 1, further including an intermediate layer between the graphene layer and the portion of the first resonator tine, where the intermediate layer includes one or more of copper, nickel, or molybdenum.

Clause 4: The device of any of clauses 1 to 3, further including a first bond pad and a second bond pad, the first resonator tine and the second resonator tine extending between the first bond pad and the second bond pad.

Clause 5: The device of clause 4, where the graphene layer extends along the first resonator tine between the first bond pad and the second bond pad.

Clause 6: The device of clause 5, where the graphene layer defines an electrical trace extending between the first bond pad and the second bond pad.

Clause 7: The device of clauses 5 or 6, where the first bond pad includes a gold coating partially overlaying the graphene layer.

Clause 8: The device of any of clauses 1 to 7, including a double-ended tuning fork including the first resonator tine and the second resonator tine.

Clause 9: The device of any of clauses 1 to 8, where the first resonator tine and the second resonator tine each include a piezoelectric material.

Clause 10: The device of clause 9, where the piezoelectric material includes quartz.

Clause 11: A vibrating beam accelerometer including the device of any of clauses 1 to 10.

Clause 12: A method for fabricating a micro-electromechanical device including a first resonator tine and a second resonator tine configured to resonate in-plane and out-of-phase with each other, the method including forming a graphene layer over at least a portion of the first resonator tine.

Clause 13: The method of clause 12, where forming the graphene layer includes chemical vapor deposition of the graphene layer from a carbon source.

Clause 14: The method of clause 13, where the first resonator tine includes quartz, where the carbon source includes methane, and where the first resonator tine is maintained at a temperature less than 750° C. during chemical vapor deposition of the graphene layer.

Clause 15: The method of any of clauses 12 to 14, where forming the graphene layer includes: depositing an intermediate layer including a metal or an alloy over at least the portion of the first resonator tine; and depositing carbon atoms on the intermediate layer to form the graphene layer on the intermediate layer.

Clause 16: The method of clause 15, where the intermediate layer includes one or more of copper, nickel, or molybdenum.

Clause 17: The method of clauses 15 or 16, further including forming an antioxidative layer between the intermediate layer and the graphene layer.

Clause 18: The method of any of clauses 15 to 17, further including, after depositing the carbon atoms, etching away the intermediate layer to allow the graphene layer to contact the portion of the first resonator tine.

Clause 19: The method of any of clauses 12 to 18, where the first resonator tine and the second resonator tine extend between a first bond pad and a second bond pad of the micro-electromechanical device, and where the graphene layer extends along the first resonator tine between the first bond pad and the second bond pad.

Clause 20: The method of clause 19, further including depositing a conductive coating partially overlaying the graphene layer on the first bond pad.

Various examples have been described. These and other examples are within the scope of the following claims.

What is claimed is:

1. A micro-electromechanical device comprising:
a first resonator tine and a second resonator tine configured to resonate in-plane and out-of-phase with each other; and
a graphene layer deposited over at least a portion of the first resonator tine.

2. The device of claim 1, wherein the graphene layer contacts a surface defined by the portion of the first resonator tine.

3. The device of claim 1, further comprising an intermediate layer between the graphene layer and the portion of the first resonator tine, wherein the intermediate layer comprises one or more of copper, nickel, or molybdenum.

4. The device of claim 1, further comprising a first bond pad and a second bond pad, the first resonator tine and the second resonator tine extending between the first bond pad and the second bond pad.

5. The device of claim 4, wherein the graphene layer extends along the first resonator tine between the first bond pad and the second bond pad.

6. The device of claim 5, wherein the graphene layer defines an electrical trace extending between the first bond pad and the second bond pad.

7. The device of claim 5, wherein the first bond pad comprises a gold coating partially overlaying the graphene layer.

8. The device of claim 1, comprising a double-ended tuning fork comprising the first resonator tine and the second resonator tine.

9. The device of claim 1, wherein the first resonator tine and the second resonator tine each comprise a piezoelectric material.

10. The device of claim 9, wherein the piezoelectric material comprises quartz.

11. A vibrating beam accelerometer comprising the device of claim 1.

12. A method for fabricating a micro-electromechanical device comprising a first resonator tine and a second resonator tine configured to resonate in-plane and out-of-phase with each other, the method comprising forming a graphene layer over at least a portion of the first resonator tine.

13. The method of claim 12, wherein forming the graphene layer comprises chemical vapor deposition of the graphene layer from a carbon source.

14. The method of claim 13, wherein the first resonator tine comprises quartz, wherein the carbon source comprises methane, and wherein the first resonator tine is maintained at a temperature less than 750° C. during chemical vapor deposition of the graphene layer.

15. The method of claim 12, wherein forming the graphene layer comprises:
depositing an intermediate layer comprising a metal or an alloy over at least the portion of the first resonator tine; and
depositing carbon atoms on the intermediate layer to form the graphene layer on the intermediate layer.

16. The method of claim 15, wherein the intermediate layer comprises one or more of copper, nickel, or molybdenum.

17. The method of claim 15, further comprising forming an antioxidative layer between the intermediate layer and the graphene layer.

18. The method of claim 15, further comprising, after depositing the carbon atoms, etching away the intermediate layer to allow the graphene layer to contact the portion of the first resonator tine.

19. The method of claim 12, wherein the first resonator tine and the second resonator tine extend between a first bond pad and a second bond pad of the micro-electromechanical device, and wherein the graphene layer extends along the first resonator tine between the first bond pad and the second bond pad.

20. The method of claim 19, further comprising depositing a conductive coating partially overlaying the graphene layer on the first bond pad.
